(19) United States
(12) Patent Application Publication
(10) Pub. No.: US 2015/0076618 A1
(43) Pub. Date: Mar. 19, 2015

(54) INTEGRATED CIRCUITS WITH A CORRUGATED GATE, AND METHODS FOR PRODUCING THE SAME

(71) Applicant: GLOBALFOUNDRIES, Inc., Grand Cayman (KY)

(72) Inventors: Ran Yan, Dresden (DE); Nicolas Sassiat, Dresden (DE); Ralf Richter, Radebeul (DE); Jan Hoentschel, Dresden (DE)

(73) Assignee: GLOBALFOUNDRIES, Inc., Grand Cayman (KY)

(21) Appl. No.: 14/031,361

(22) Filed: Sep. 19, 2013

(51) Int. Cl. H01L 29/423; H01L 29/10; H01L 29/40

(52) U.S. Cl. CPC H01L 29/42376; H01L 29/401; H01L 29/1037
USPC 257/401; 438/585

(57) ABSTRACT

Methods and apparatus are provided for an integrated circuit. The method includes forming a corrugation mask on a substrate, and forming a channel corrugation on the substrate. The corrugation mask is removed from the substrate, and a gate insulator is formed overlying the channel corrugation on the substrate. A gate is formed overlying the channel gate insulator.

### TECHNICAL FIELD

The technical field generally relates to integrated circuits and methods for producing integrated circuits, and more particularly relates to integrated circuits with transistors having corrugations in the transistor gate and channel and methods for producing the same.

### BACKGROUND

Transistors such as metal oxide semiconductor field effect transistors (MOSFETs) or simply field effect transistors (FETs) or MOS transistors are the core building blocks of the vast majority of semiconductor integrated circuits (ICs). A FET includes source and drain regions between which a current can flow through a channel under the influence of a bias applied to a gate electrode that overlies the channel and that is separated from the channel by a gate dielectric structure. The channel length extends from the source to the drain, and the channel width runs perpendicular to the length.

The amount of current that passes through a field effect transistor (FET) in the “on” state depends, in part, on the width of a channel positioned under a gate of the FET. The “on” current is given by the formula Iₒₙ≈μ*Cₒₓ*Wₛᵢ/L_{g}*(V_{dd}−Vₜₕ)², where Iₒₙ is the “on” current, μ is the carrier mobility, Cₒₓ is the gate oxide capacitance, Wₛᵢ is the gate width, L_{g} is the gate length, V_{dd} is the drain voltage, and Vₜₕ is the threshold voltage. As can be seen, an increase in the width of the channel (Wₛᵢ) results in a larger “on” current. While higher “on” currents are desirable for many applications, there is pressure to reduce the size of integrated circuits and the electronic components, such as transistors, used in those integrated circuits. Thus, simply increasing the width of the gate to increase the “on” current is not desirable.

Accordingly, it is desirable to provide systems and methods for producing a FET with an increased channel width. In addition, it is desirable to provide a FET with higher “on” current values without utilizing more of the substrate surface area. Furthermore, other desirable features and characteristics of the present embodiment will become apparent from the subsequent detailed description and the appended claims, taken in conjunction with the accompanying drawings and this background of the invention.

### BRIEF SUMMARY

A method is provided for producing an integrated circuit. The method includes forming a corrugation mask on a substrate, and forming a channel corrugation on the substrate. The corrugation mask is removed from the substrate, and a gate insulator is formed overlying the channel corrugation on the substrate. A gate is formed overlying the channel gate insulator.

In a different embodiment, a method is provided for producing an integrated circuit. The method includes forming a gate insulator overlying a substrate, and forming a gate overlying the gate insulator. The gate is formed to include a gate corrugation on a gate bottom surface, and the gate corrugation increases an effective gate width. A source and a drain are formed on opposite sides of the gate insulator.

An apparatus is provided for an integrated circuit. The integrated circuit includes a substrate with a source and a drain. A gate overlies the substrate between the source and drain, and the gate has a gate bottom surface. The gate bottom surface includes a corrugation.

### BRIEF DESCRIPTION OF THE DRAWINGS

The present embodiments will hereinafter be described in conjunction with the following drawing figures, wherein like numerals denote like elements, and wherein:

FIG. 1 illustrates an exploded perspective view of an exemplary embodiment of a field effect transistor;

FIG. 2, in an exemplary embodiment, illustrates a theoretical straightening of the gate bottom surface to demonstrate an effective gate width;

FIGS. 3-6 illustrate, in cross sectional views, various exemplary embodiments of a field effect transistor with different gate corrugation, channel corrugation, and gate insulator corrugation patterns;

FIGS. 7-13 illustrate, in cross sectional views, a portion of the integrated circuit and methods for its fabrication in accordance with exemplary embodiments; and

FIG. 14 illustrates a perspective view of a portion of an integrated circuit with an exemplary embodiment of a field effect transistor including gate corrugations.

### DETAILED DESCRIPTION

The following detailed description is merely exemplary in nature and is not intended to limit the various embodiments or the application and uses thereof. Furthermore, there is no intention to be bound by any theory presented in the preceding background or the following detailed description.

As noted above, the “on” current of a FET is directly related to the channel width. Various embodiments of FETs contemplated herein utilize corrugated channels to increase the “on” current of the FETS. Corrugations increase the effective width of a channel and without increasing other dimensions of the channel or gate. In this regard, corrugations increase the “on” current of a FET for a fixed gate size. The corrugations increase the effective width of a channel in the same way that a crooked line between two points is longer than a straight line between the same two points.

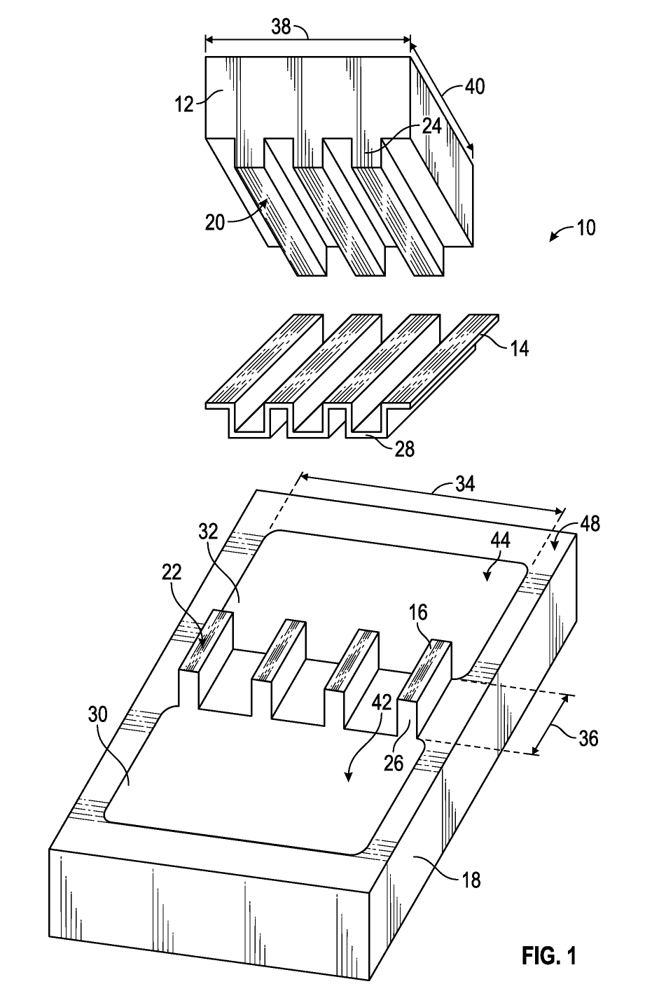

An exploded view of an exemplary embodiment of a field effect transistor (FET) 10 is illustrated in FIG. 1. The FET 10 includes a gate 12 overlying a gate insulator 14, which in turn overlies a channel 16. As used herein, “overlying” means “on” such that the gate 12 physically contacts the gate insulator 14, or “over” such that another material layer may lie in between the gate 12 and the channel 16. The gate 12 has a gate bottom surface 20 over and abutting the gate insulator 14, and the gate insulator 14 is over and abutting a channel top surface 22. The gate bottom surface 20 has one or more gate corrugations 24, and the channel top surface 22 has one or more channel corrugations 26 that aligns with the gate corrugation(s) 24. The gate insulator 14 has one or more gate insulator corrugations 28 that aligns with both the gate corrugation(s) 24 and the channel corrugation(s) 26, so the gate 14, the gate insulator 14, and the channel 16 fit together like pieces in a puzzle. A corrugation is a groove or a ridge on a surface, so the surface has a different height at different locations. The gate 12 can be a wide variety of materials, including polysilicon, a refractory metal, or other materials. The gate insulator 14 can also be a wide variety of materials, including silicon oxide, hafnium silicate, or many other dielectric materials. The channel 16 is generally formed within a semiconductor substrate. As used herein, the term “semiconductor substrate” will be used to encompass semiconductor materials conventionally used in the semiconductor industry from which to make electrical devices. Semiconductor materials include monocrystalline silicon materials, such as the relatively pure or lightly impurity-doped monocrystalline silicon materials typically used in the semiconductor industry, as well as polycrystalline silicon materials, and silicon admixed with other elements such as germanium, carbon, and the like. In addition, “semiconductor material” encompasses other materials such as relatively pure and impurity-doped germanium, gallium arsenide, zinc oxide, glass, and the like. The semiconductor material is preferably a silicon substrate. The silicon substrate may be a bulk silicon wafer or may be a thin layer of silicon on an insulating layer (commonly known as silicon-on-insulator or SOI) that, in turn, is supported by a carrier wafer.

The substrate 18 includes a source 30 and a drain 32 positioned on opposite sides of the channel 16, so the source 30 and drain 32 are also on opposite sides of the gate insulator 14 and the gate 12. The channel 16 has a channel length 34, indicated by double headed arrows, extending from the source 30 to the drain 32, and a channel width 36, indicated by double headed arrows, perpendicular to the channel length 34. The gate 12 has a gate length 38, indicated by double headed arrows, and a gate width 40, indicated by double headed arrows, that correspond to the channel length 24 and the channel width 26. The gate corrugation 24, the channel corrugation 26, and the gate insulator corrugation 28 all extend along, or parallel to, the gate length 40 and the channel length 36, so the corrugations 24, 26, 28 run from the source 30 to the drain 32.

In an exemplary embodiment, the source 30 has a source surface 42 that is planar, and the drain 32 has a drain surface 44 that is planar. The source surface 42 and the drain surface 44 are the upper, exposed portions of the source 30 and drain 32, respectively, which are also a portion of a substrate surface 48. In other embodiments, the channel corrugation 26 can continue and extend through the source 30 and/or the drain 32, as well as the substrate 18 beyond the source 30 and drain 32. The substrate 18 is generally horizontal, so the source 30, drain 32, and channel 16 are generally horizontal as well. The substrate 18 has a substrate surface 48 that can include corrugations, so the substrate surface 48 may not be completely flat. However, in an exemplary embodiment, the substrate surface 48 extends in a generally horizontal direction from the source surface 42 and the drain surface 44.

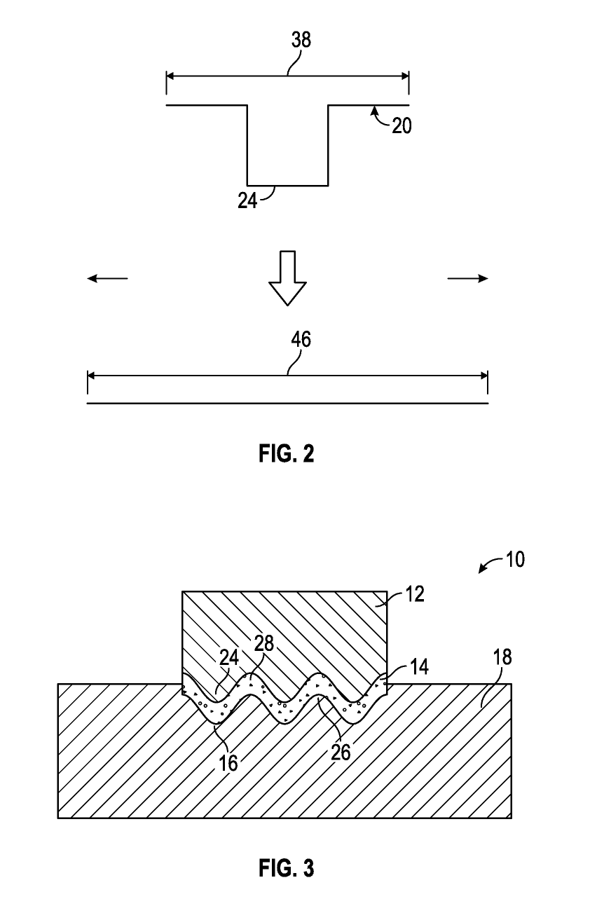

Reference is now made to an exemplary embodiment shown in FIG. 2, with continuing reference to FIG. 1. A cross section of the gate bottom surface 20 shows a gate corrugation 24 and the gate width 38. There is an effective gate width 46 that can be visualized by “straightening” the line formed by the gate bottom surface 20, where the outwardly extending arrows indicate a theoretical “straightening” of the gate bottom surface 20. The area of contact between the gate 12 and the gate insulator 14 is represented by multiplying the effective gate width 46 by the gate length 40, so the gate corrugations 24 increase that surface area. The effective gate width 46 determines the “on” current for the FET 10, as opposed to the gate width 38 that does not account for the gate corrugation 24, because the effective gate width 46 represents the area in the channel 16 available for conducting electrical current. The gate corrugation 24 increases the effective gate width 46, which produces a higher “on” current than for an FET 10 with similar dimensions and materials but with a flat gate bottom surface 20 and channel top surface 22. Therefore, the “on” current of the FET 10 is increased by adding a gate corrugation 24, and the corresponding channel corrugation 26 and gate insulator corrugation 28.

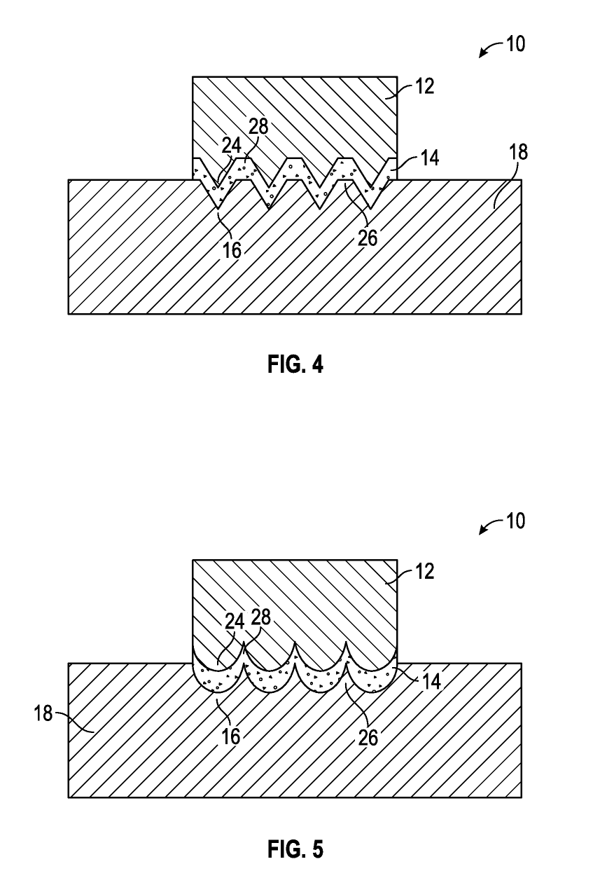

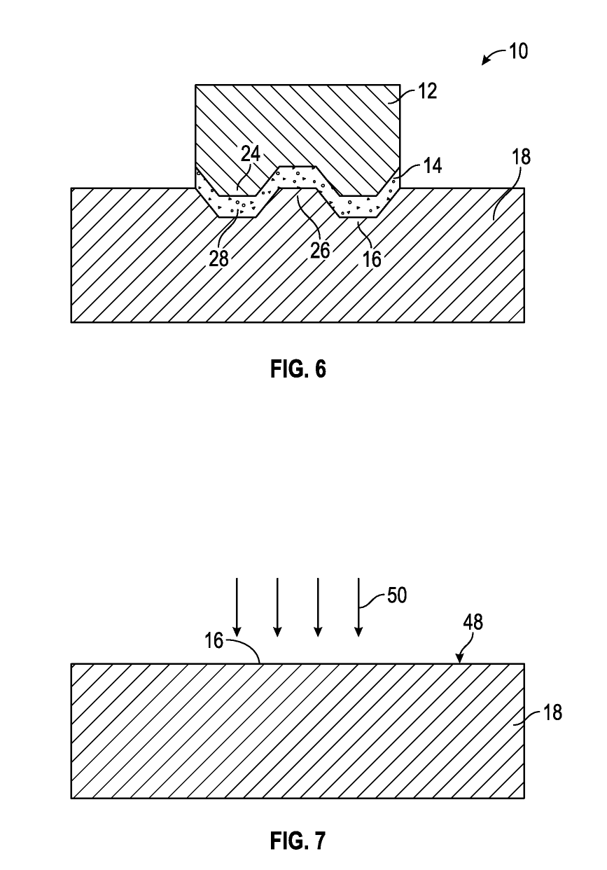

Many different types and styles of gate corrugations 24 are possible, and the different types and styles of gate corrugations 24 are matched by the channel corrugations 26 and the gate insulator corrugations 28. For example, the exemplary embodiment in FIGS. 1 and 2 illustrate a crenulated gate corrugation 24 with vertical walls and sharp, 90 degree angles for each change in direction of the gate bottom surface 20. An alternate exemplary embodiment is illustrated in FIG. 3, where the gate corrugation 24 has a wave shape, or a curved shape with no sharp angles when the direction of the gate bottom surface 20 changes. FIG. 4 illustrates another exemplary embodiment where the gate corrugation 24 has an angled shape that produces a zig zag pattern. FIG. 5 illustrates an embodiment with a scalloped gate corrugation 24 that has a mixture of an angled shape and a curved shape. FIG. 6 illustrates another embodiment with an angled shape that produces a sloped wall crenulated pattern. Many different shapes are possible for the gate corrugation 24, and each shape increases the “on” current for the FET 10.

Reference is now made again to FIG. 1. A wide variety of methods can be used to produce the FET 10, and different embodiments of the gate corrugation 24 can be incorporated into the different production methods. For example, the gate corrugation 24 can be incorporated into gate first or gate last production methods, bulk crystalline silicon substrates or silicon on insulator substrates, “N” channel FETs 10 or “P” channel FETs 10, polycrystalline silicon gate FETs, refractory metal gates, etc. The channel corrugation 26 is formed before forming the final gate insulator 14, and the shape of the channel corrugation 26 is incorporated into the gate insulator 14 and the gate bottom surface 20 during manufacture.

An exemplary embodiment for manufacturing a FET 10 begins with reference to FIG. 7. The substrate 18 is implanted with a channel dopant 50, and then thermally annealed. A channel dopant 50 of boron ions are used for an “N” channel FET, and phosphorous or arsenic ions are used for a “P” channel FET, but other types of ions could be used in alternate embodiments. The channel dopant 50 is implanted into the substrate 18 to adjust the threshold voltage for the transistor that will be manufactured. In the embodiment illustrated, the substrate 18 is implanted before the corrugation forming process begins. However, in other embodiments, the channel dopant 50 is implanted into the substrate 18 after the corrugations are formed.

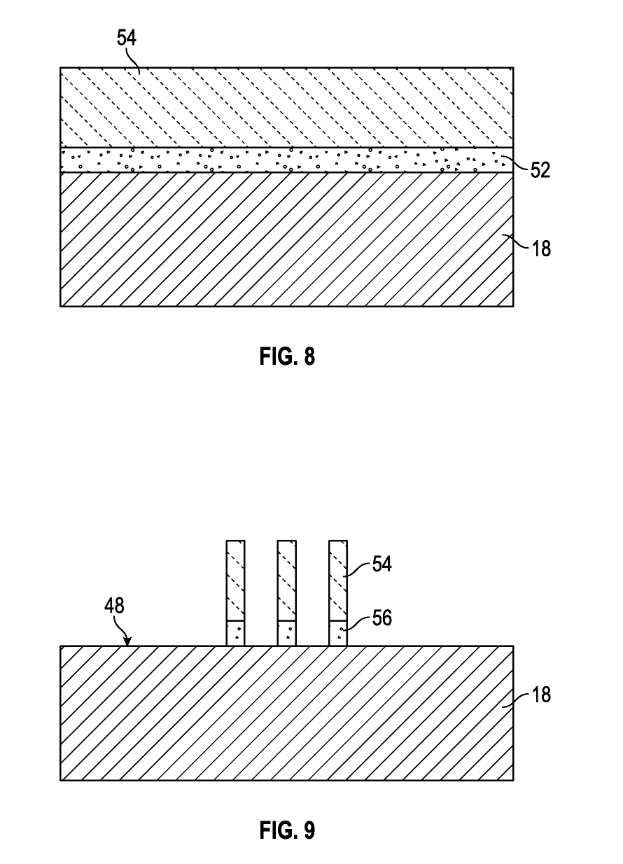

Reference is now made to the exemplary embodiment illustrated in FIG. 8. A corrugation mask layer 52 is formed overlying the substrate 18, and a corrugation mask photoresist 54 is formed overlying the corrugation mask layer 52. In an exemplary embodiment the corrugation mask layer 52 is silicon nitride, which is deposited by reacting ammonia and dichlorosilane in a low pressure chemical vapor deposition furnace. The corrugation mask photoresist 54 is spin coated onto the corrugation mask layer 52, and then patterned and developed to leave corrugation mask photoresist 54 overlying selected portions of the substrate 18. The corrugation mask layer 52 is patterned with a mask and electromagnetic radiation, such as light, and an organic solvent is used to remove the unwanted areas. The corrugation mask layer 52 is then etched, such as with nitrogen trifluoride in a hydrogen plasma, to produce the corrugation mask 56 illustrated in FIG. 9. In an exemplary embodiment, the corrugation mask 56 remains overlying the substrate 18 where the source and drain will be positioned (not shown) while the channel corrugations are formed, so the future source and drain will not have corrugations. The remaining corrugation mask photoresist 54 is then removed, such as with an oxygen containing plasma.

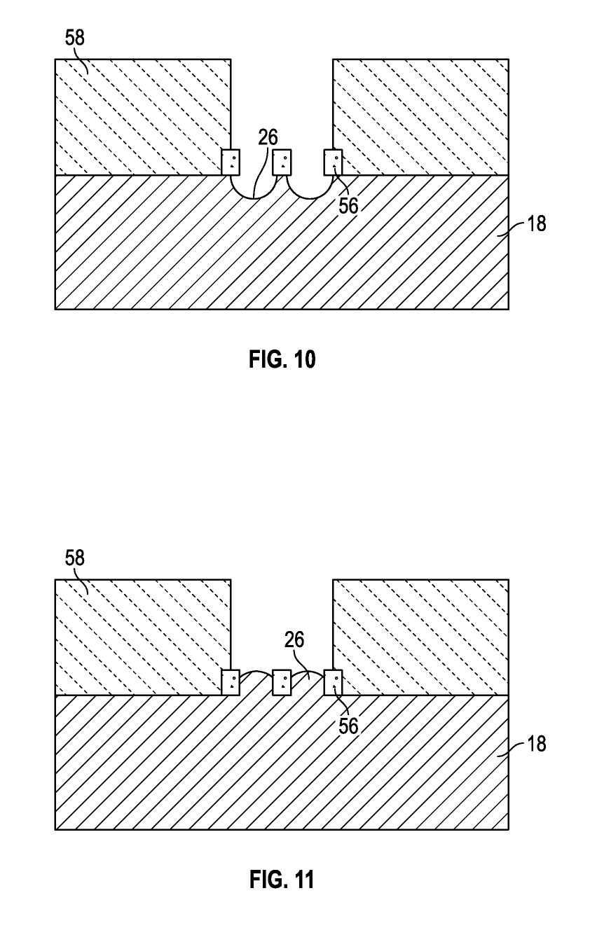

Reference is now made to an exemplary embodiment illustrated in FIG. 10. A corrugation formation photoresist 58 is formed over the substrate 18 and the corrugation mask 56, such as with spin coating. The corrugation formation photoresist 58 is then patterned and developed to expose the substrate 18 at the location where the channel corrugation 26 will be formed. Many embodiments of the channel corrugation 26 are possible, as discussed above. For example, an isotropic etch of the silicon in the substrate 18 produces a curved trough, as illustrated in FIG. 10. A chemical plasma etch with xenon difluoride can be used, or a wet etch with nitric acid and hydrofluoric acid can also be used. This curved shape can be extended to produce a scalloped pattern, as illustrated in FIG. 5. A straight walled, crenulated pattern is produced by a synergetic reactive ion etch, using chlorine gas, as illustrated in FIG. 1. An angled shape with a sloped wall crenulated pattern is produced by an anisotropic wet etch of monocrystalline silicon with potassium hydroxide solution, where the bottom of the cavity and the sloped sides are different silicon crystal planes. The sloped wall crenulated pattern is illustrated in FIG. 6, and extending this etch produces the zig zag pattern illustrated in FIG. 4. The channel corrugation 26 can be manufactured by depositing material instead of, or in conjunction with, etching, as illustrated in FIG. 11. Polysilicon can be formed with plasma enhanced chemical vapor deposition using silane, and the deposited polysilicon tends to produce rounded bump shapes. These rounded bump shapes can be combined with the rounded trough shapes from an isotropic etch to produce the wave shaped channel corrugation 26 illustrated in FIG. 3, where successive, offset corrugation masks 56 are used for the deposition and etching steps. The polysilicon can be doped during deposition to adjust the conductivity, as desired. In another embodiment, crystalline silicon can be epitaxially grown using silane in a vapor phase epitaxy.

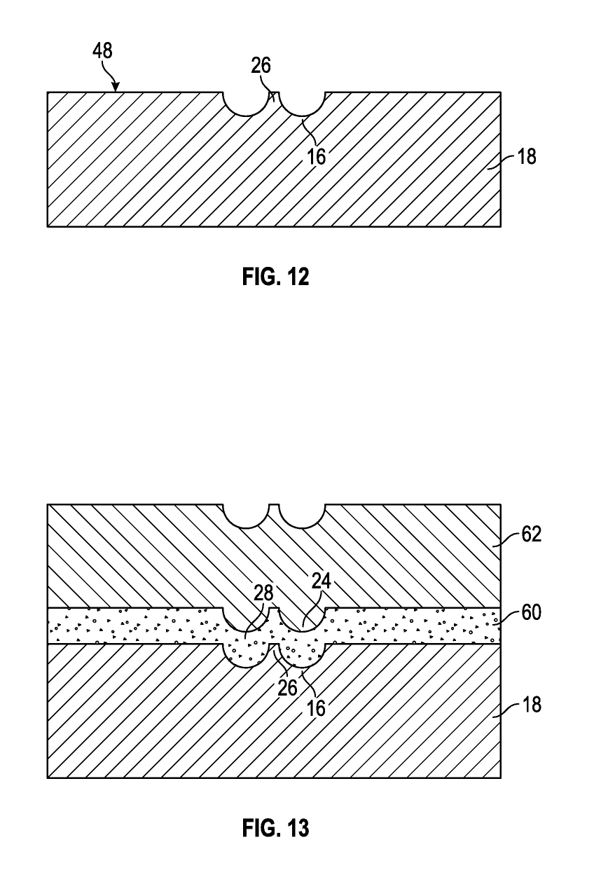

Reference is now made to the embodiment shown in FIG. 12, with continuing reference to FIG. 10. The corrugation formation photoresist 58 is removed, such as with an oxygen containing plasma, and the corrugation mask 56 is selectively removed, such as with a hot phosphoric acid wet etch. This leaves the substrate 18 with channel corrugations 26 where the channel will be positioned.

Reference is now made to an exemplary embodiment illustrated in FIG. 13. A gate insulator layer 60 of silicon oxide is formed by exposing the substrate 18 to an oxidizing ambient at elevated temperatures, such as oxygen and water at temperatures from about 900° C. to about 1,200° C. The gate insulator layer 60 grows from the exposed silicon, so the gate insulator layer 60 incorporates the channel corrugations 26 from the substrate 18. A gate layer 62 is then deposited overlying the gate insulator layer 60. The gate layer 62 is polysilicon in one embodiment, which is deposited by low pressure chemical vapor deposition in a silane ambient. The gate layer 62 conforms to the shape of the gate insulator layer 60, and the gate insulator layer 60 conforms to the shape of the substrate 18. Therefore, the channel corrugation 26 in the substrate 18 is duplicated by an aligned gate insulator corrugation 28 in the gate insulator layer 60, and a gate corrugation 24 in the gate layer 62. An upper surface of the gate 12 may or may not include a corrugation, and the performance of the FET 10 is not significantly changed by a corrugation on the upper surface of the gate 12.

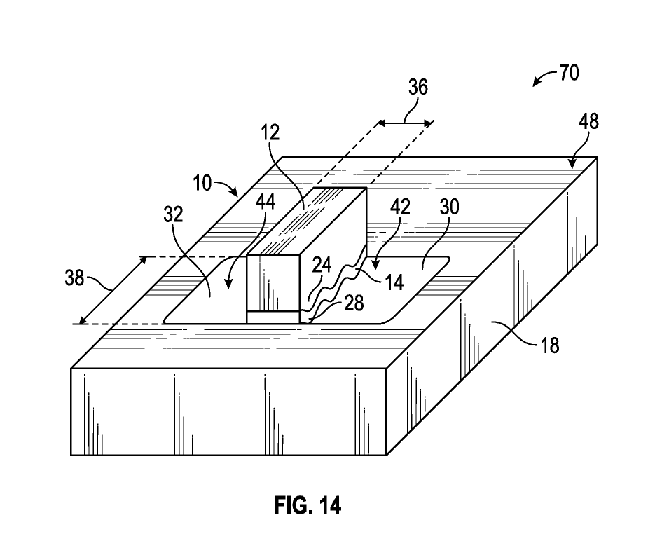

Reference is now made to FIG. 14, with continuing reference to FIG. 13. The manufacturing process for the FET 10 is continued using further processing steps well known in the art. For example, the gate layer 62 and the gate insulator layer 60 may be etched to form the gate 12 and the gate insulator 14, ion implantation may be performed to form the source 30 and drain 32 regions, and electrical contacts may be formed to the source 30 and drain 32 regions and to the gate 12. This conventional processing may further include, for example, depositing interlayer dielectrics, etching contact vias, filling the contact vias with conductive plugs, and the like as are well known to those of skill in the art of fabricating integrated circuits 70. Fabrication of the integrated circuit 70 may thereafter continue with further processing steps that can be performed to complete the device, as are well-known in the art. The subject matter disclosed herein is not intended to exclude any subsequent processing steps to form and test the completed integrated circuit 70 as are known in the art. Furthermore, with respect to any of the process steps described above, one or more heat treating and/or annealing procedures can be employed after the deposition of a layer, as is commonly known in the art.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the application in any way. Rather, the foregoing detailed description will provide those skilled in the art with a convenient road map for implementing one or more embodiments, it being understood that various changes may be made in the function and arrangement of elements described in an exemplary embodiment without departing from the scope, as set forth in the appended claims.

1. An integrated circuit comprising:
a substrate;
a source within the substrate;
a drain within the substrate; and
a gate overlying the substrate between the source and the drain, wherein the gate comprises a gate bottom surface, and wherein the gate bottom surface comprises a gate corrugation.

2. The integrated circuit of claim 1 further comprising a gate insulator, wherein the gate overlies the gate insulator, and wherein the gate insulator comprises a gate insulator corrugation aligned with the gate corrugation.

3. The integrated circuit of claim 1 further comprising a channel positioned within the substrate between the source and the drain, wherein the channel further comprises a channel corrugation aligned with the gate corrugation.

4. The integrated circuit of claim 3 wherein the channel corrugation extends through the source and the drain.

5. The integrated circuit of claim 1 wherein the source comprises a source surface that is planar, and the drain comprises a drain surface that is planar.

6. The integrated circuit of claim 1 wherein the gate has a gate length extending from the source to the drain, and the gate corrugation extends parallel with the gate length.

7. The integrated circuit of claim 1 wherein the source comprises a source surface, the drain comprises a drain surface, and the substrate comprises a substrate surface, and wherein the substrate surface extends horizontally from the source surface and the drain surface.

8. The integrated circuit of claim 1 wherein the gate corrugation comprises a curved shape.

9. The integrated circuit of claim 1 wherein the gate corrugation comprises an angled shape.

10. An integrated circuit comprising:
a field effect transistor (FET) comprising a channel, a gate insulator overlying the channel, and a gate overlying the gate insulator; and
wherein the channel comprises a channel top surface, and wherein the channel top surface comprises a channel corrugation.

11. The integrated circuit of claim 10 wherein the channel comprises a channel length, and wherein the channel corrugation extends parallel with the channel length.

12. The integrated circuit of claim 10 wherein the channel corrugation comprises a curved shape.

13. The integrated circuit of claim 10 wherein the channel corrugation comprises a crenulated shape.

14. The integrated circuit of claim 10 wherein an “on” current of the FET is increased by the channel corrugation.

15. The integrated circuit of claim 10 wherein the gate insulator comprises a gate insulator corrugation aligned with the channel corrugation.

16. The integrated circuit of claim 10 further comprising:
a substrate comprising a substrate surface;
a source positioned within the substrate, wherein the source comprises a source surface;
a drain positioned within the substrate, wherein the drain comprises a drain surface;
wherein the channel is positioned within the substrate between the source and the drain; and
wherein the substrate surface extends horizontally from the source surface and the drain surface.

17. The integrated circuit of claim 16 wherein the source surface is planar and the drain surface is planar.

18. The integrated circuit of claim 10 wherein the channel corrugation comprises a plurality of channel corrugations.

19. The integrated circuit of claim 10 wherein the gate comprises a gate bottom surface, and wherein the gate bottom surface comprises a gate corrugation aligned with the channel corrugation.

20. A method of producing an integrated circuit comprising:
forming a corrugation mask on a substrate;
forming a corrugation on the substrate;
removing the corrugation mask from the substrate;
forming a gate insulator overlying the corrugation on the substrate; and
forming a gate overlying the gate insulator.
